(19) United States
(12) Patent Application Publication
(10) Pub. No.: US 2013/0337653 A1
(43) Pub. Date: Dec. 19, 2013

(54) SEMICONDUCTOR PROCESSING APPARATUS WITH COMPACT FREE RADICAL SOURCE

(71) Applicant: ASM IP Holding B.V., Almere (NL)

(72) Inventors: Alexey Y. Kovalgin, Almere (NL); Antonius A. I. Aarnink, Almere (NL)

(21) Appl. No.: 13/918,094

(22) Filed: Jun. 14, 2013

Related U.S. Application Data
(60) Provisional application No. 61/660,071, filed on Jun. 15, 2012.

(51) Int. Cl. H01L 21/306; H01L 21/02

(52) U.S. Cl. CPC H01L 21/306; H01L 21/02104
USPC 438/706; 438/765; 118/723 R; 156/345.37

(57) ABSTRACT

A semiconductor processing apparatus (1), comprising: a substrate processing chamber (158), defining a substrate support location (156) at which a generally planar semiconductor substrate (300) is supportable; and at least one free radical source (200), including: a precursor gas source (250); an electric resistance heating filament (244); a sleeve (220) with a central sleeve axis (L), wherein said sleeve defines a reaction space (222) that accommodates the heating filament (244), and wherein said sleeve includes an inlet opening (224) via which the reaction space is fluidly connected to the precursor gas source (250), and an outlet opening (228) via which the reaction space is fluidly connected to the substrate processing chamber (158), said inlet and outlet openings (224, 228) being spaced apart along the central sleeve axis (L).

### FIELD OF THE INVENTION

The present invention relates to a semiconductor processing apparatus for processing semiconductor substrates by exposing such substrates to free radicals.

### BACKGROUND

The processing of a semiconductor substrate, e.g. the deposition of a thin film thereon, may involve exposing the substrate to free radicals. The generation of such radicals may be effected through the use of a plasma, but this approach entails several drawbacks. For one, plasma sources may be relatively bulky. In addition, a plasma may typically produce additional and undesired particles, such as electrons, ions, and highly energetic photons, that, upon contact with the substrate, may disadvantageously affect the treatment process, e.g. by being incorporated into the film that is deposited, or by otherwise damaging it.

### SUMMARY OF THE INVENTION

It is an object of the present invention to provide for a semiconductor processing apparatus with a compact, non-plasmatic free radical source, capable of controllably generating free radicals, and preferably without the production of additional, reactive particles that may disadvantageously effect the processing of a substrate.

To this end, a first aspect of the present invention is directed to a semiconductor processing apparatus. The semiconductor processing apparatus may comprise a substrate processing chamber, defining a substrate support location at which a generally planar semiconductor substrate is supportable. The semiconductor processing apparatus may further comprise at least one free radical source, including a precursor gas source; an electric resistance heating filament; and a tubular sleeve with a central sleeve axis, wherein said sleeve defines a reaction space that accommodates the heating filament, and wherein said sleeve includes an inlet opening via which the reaction space is fluidly connected to the precursor gas source, and an outlet opening via which the reaction space is fluidly connected to the substrate processing chamber, said inlet and outlet openings being spaced apart along the central sleeve axis.

A second aspect of the present invention is directed to a method of exposing a semiconductor substrate to free radicals. The method may include providing a semiconductor processing apparatus according to the first aspect of the invention; providing a substrate at the substrate support location in the processing chamber of the semiconductor processing apparatus; heating the heating filament to a temperature of at least 1000° C., preferably at least 1500° C., and more preferably at least 1750° C. (partly depending on the precursor gas used); and providing a flow of precursor gas from the precursor gas source into the reaction space of the sleeve, thereby causing dissociation of the precursor gas into at least one free radical species at the heated heating filament, and subsequently providing a flow of the free radical species from the reaction space to the substrate support location in the processing chamber, so as to expose the substrate to the free radical species. The method may comprise maintaining a vacuum pressure below 1 Pa, and preferably below 0.1 Pa, inside the processing chamber, in particular to increase the mean free path length of the free radicals.

These and other features and advantages of the invention will be more fully understood from the following detailed description of certain embodiments of the invention, taken together with the accompanying drawings, which are meant to illustrate and not to limit the invention.

### BRIEF DESCRIPTION OF THE DRAWINGS

FIG. 1 schematically shows a perspective view of an exemplary embodiment of a semiconductor processing apparatus according to the present invention;

FIG. 2 is a schematic top view of the semiconductor processing apparatus shown in FIG. 1;

FIG. 3 is a schematic cross-sectional side view of the semiconductor processing apparatus shown in FIGS. 1 and 2, taken along line B-B in FIG. 2;

FIG. 4 is a detail taken from FIG. 3, illustrating the free radical source of the semiconductor processing apparatus;

FIG. 5 schematically illustrates results of an experiment with the semiconductor processing apparatus shown in FIGS. 1-4, wherein a tellurium film on a silicon substrate was etched with atomic hydrogen produced by the free radical source under various processing chamber pressures; and

FIG. 6 schematically illustrates results of an experiment with the semiconductor processing apparatus shown in FIGS. 1-4, wherein a tellurium film on a silicon substrate was etched with atomic hydrogen, and wherein the free radical source was alternately switched on and off.

### DETAILED DESCRIPTION

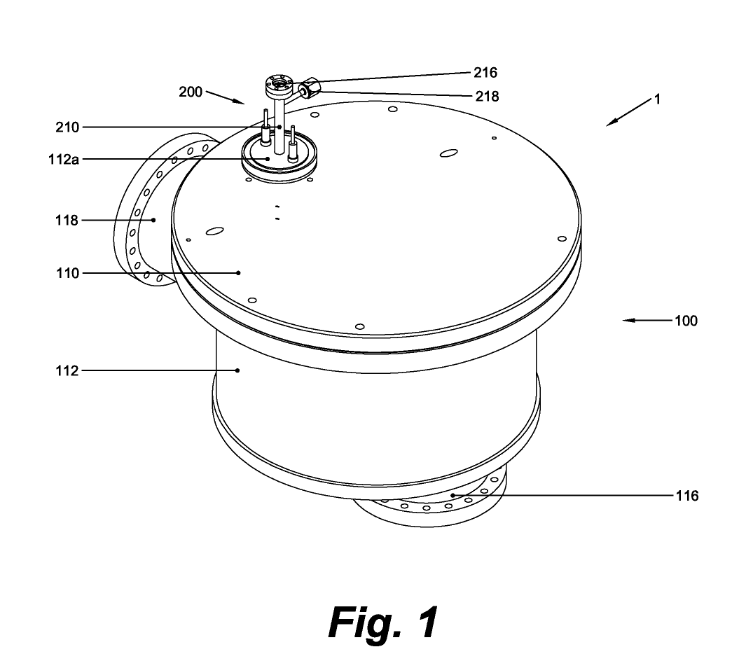

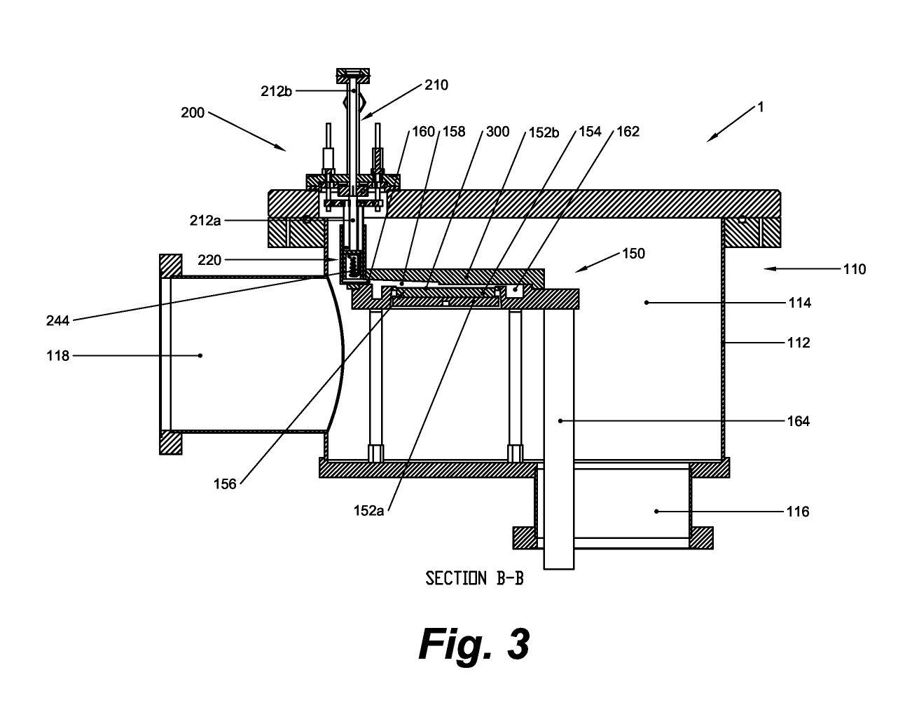

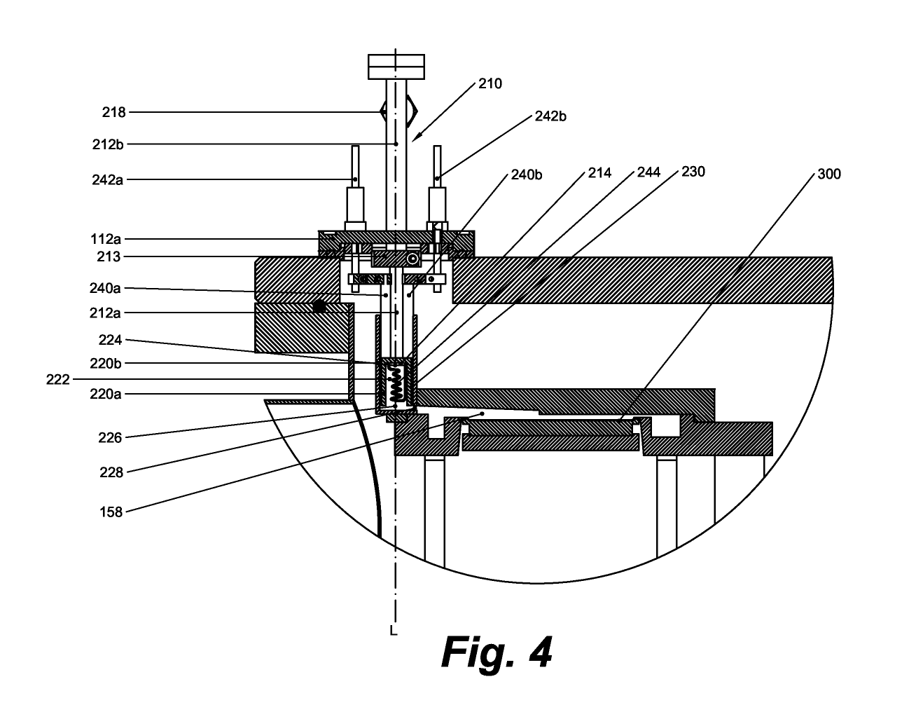

FIGS. 1-4 schematically illustrate in a perspective view, a top view and a cross-sectional side view, and a detailed/enlarged cross-sectional side view, respectively, an exemplary embodiment of a semiconductor processing apparatus 1 according to the present invention. The embodiment of the semiconductor processing apparatus 1 shown in FIG. 1 concerns a single-substrate reactor, but it is contemplated that alternative embodiments may be multi-substrate/batch reactors or furnaces, capable of processing a plurality of substrates at a time. Referring now to FIGS. 1-4.

The semiconductor processing apparatus 1 may include a reactor 100, comprising an outer reactor 110 that accommodates an inner reactor 150. The outer reactor 110 may include an outer wall 112 that defines an outer reactor chamber 114. The outer reactor 114 chamber may be coupled to a substrate handling station of a cluster tool (not shown) via a substrate transport passage 118, so as to enable the transfer of substrates into and from the reactor 100. In addition, the outer reactor 114 may be coupled to a vacuum pump (not shown) via a vacuum exhaust 116, so as to enable the pressure in the outer reactor chamber 114 to be reduced to appropriate vacuum levels.

The inner reactor 150 may include a bottom wall 152a and a top wall 152b, which may be positioned opposite to each other and at least partially define an inner reactor chamber or process chamber 158 between them. The lower wall 152a of the inner reactor 150 may include a wafer tray 154 that defines a substrate support location 156 at which a generally planar semiconductor substrate 300, e.g. a silicon wafer, is supportable. Either wall 152a,b of the inner reactor may incorporate, or have associated with it, a heating element (not shown) for heating a substrate 300 received at the substrate support location 156 to an appropriate temperature. The inner reactor 150 may further include at least one inlet opening 160 via which process materials are introducible into the process chamber 158, and at least one outlet opening 162 via which process materials are dischargeable from the process chamber 158. The at least one outlet opening 162 may be fluidly connected to a gas exhaust 164.

The semiconductor processing apparatus 1 may also include a free radical source 200.

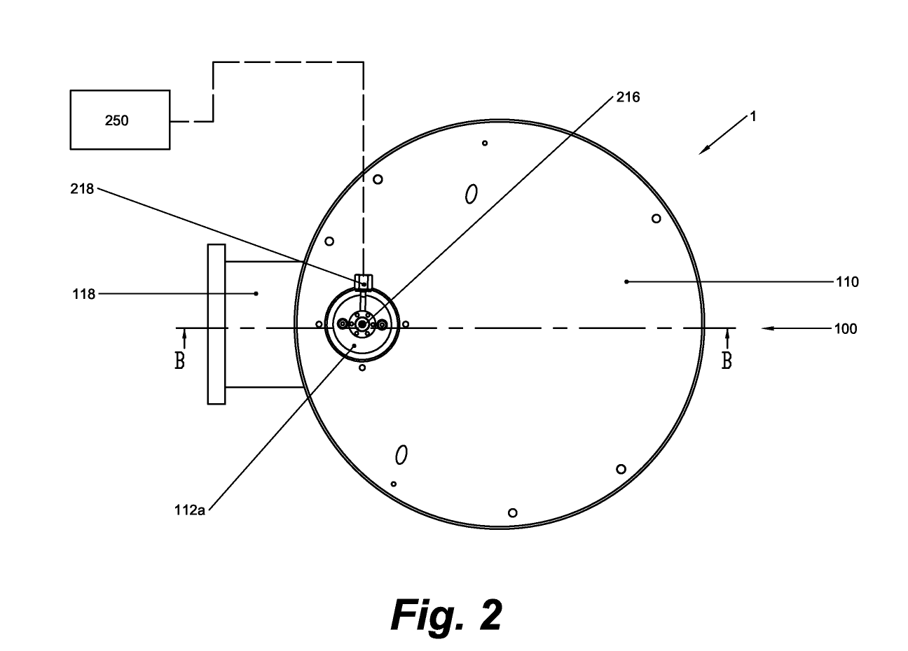

The free radical source 200 may include a precursor gas supply tube assembly 210, including a precursor gas supply tube or conduit 212 for supplying a precursor gas from a precursor gas supply source 250 (schematically shown in FIG. 2) to a reaction space 222 of the free radical source 200, to be discussed hereafter. As in the depicted embodiment, the precursor gas supply tube 212 may include two substantially vertically oriented, straight, and mutually telescopically arranged tubes 212a, 212b. The outer tube 212b, which may be made from metal, may extend from outside of the reactor 100 inward into the outer reactor chamber 114 through a cover portion 112a of the wall of the outer reactor 112 that airtightly or sealingly engages the outer tube 212b. The part of the outer tube 212b disposed outside of the reactor 100 may define a precursor gas inlet 218, and, optionally, at an upper extremity thereof, a sight-glass 216 that enables inspection of the free radical source 200, and in particular of the temperature of the heating filament 244 thereof, during operation, for instance by means of a pyrometer. A lower end of the outer tube 212b, configured to slidingly receive the inner tube 212a of the precursor gas supply tube 212, may be axially slotted, and be provided with a clamp ring 213 with a set screw or the like. Tightening the clamp ring 213 on the axially slotted end of the outer tube 212b may exert a squeezing action that ensures that the slotted end of the outer tube 212b firmly engages the inner tube 212a, and thus fixes the mutual positions of the inner and outer tubes 212a, 212b. Conversely, loosening the clamp ring 213 may release the inner tube 212a and enable its position relative to the outer tube 212b to be adjusted by sliding it further into or out of the outer tube 212b. The inner tube 212a may preferably be made of a ceramic material, e.g. aluminum oxide.

The precursor gas source 250 that may be fluidly connected to the precursor gas inlet 218 may provide for a molecular gas that dissociates upon contact with the (heated) heating filament 244 of the free radical source 200 to yield the desired free radicals. In this context, the term ‘free radical’ may be construed to refer to atoms, molecules or ions with at least one unpaired electron or an open shell configuration. Molecular gases of particular interest may include molecular hydrogen (H₂) and ammonia (NH₃), which may both give rise to atomic hydrogen (H) on dissociation, and nitrous oxide (N₂O), which may give rise to atomic oxygen (O). Other gases of interest may include hydrides of silicon (including higher order silanes such as disilane and trisilane), germanium (e.g. GeH₄), boron (e.g. B₂H₆), phosphorus (e.g. PH₃) and arsine (e.g. AsH₃). During operation, the flow of the precursor gas to the reaction space 222 of the free radical source 200 may be in a range from 1 to 100 sccm, preferably in a range from 5 to 30 standard cubic centimeters per minute (sccm).

The free radical source 200 may further include a sleeve 220, which may preferably be made from a ceramic material, such as aluminum oxide (Al₂O₃). Aluminum oxide is easily machinable, a proper electric insulator, and causes little or no contamination of the process environment under extreme heating. As in the depicted embodiment, the sleeve 220 may include an outer sleeve 220b, and an inner sleeve 220a that is co-axial with the outer sleeve 220b and axially movably received therein.

The inner sleeve 220a may be generally cup-shaped, and have a tubular, e.g. cylinder jacket-shaped, body which is capped with a generally flat top wall that is integrally formed with the body. The top wall may be provided with a central inlet opening 224, and the lower, open end of the inner tube 212a of the precursor gas supply tube 212 may extend through the central opening, such that a circumferential edge of the central opening in the top wall of the inner sleeve 220a is supported on a radially outwardly extending support flange 214 provided at the lower end of the inner tube 212a. The body of the inner sleeve 220a may define a reaction space 222 of the free radical source 200, and it is understood that (the lower end of the inner tube 212a of) the precursor gas supply tube 212 may discharge into this reaction space 222. The bottom end of the inner sleeve 220a may be open, and define an outlet opening through which process materials may be discharged from the reaction space 222.

The reaction space 222 may accommodate an electric resistance heating filament 244. The filament 244 may preferably be a wire, a ribbon, or the like, and be wound into a coil-like structure such that it includes a plurality of windings that extend helically around a central, longitudinal axis L of the sleeve 220. The heating filament 244 may preferably be at least partially made of metal, such as in particular tungsten, capable of withstanding temperatures well above 1000° C., and preferably above 1500 ° C. In case an external surface area of the heating filament is denoted A, and a volume of the reaction space is denoted V, a ratio A/V may preferably be equal to or greater than 1.5/mm, so as to ensure that the basic configuration of the inner sleeve 220a and the heating filament 224 is suitable to intensify contact between any precursor gas discharged into the reaction space 222 from the precursor gas supply tube 212 and the surface of the filament 244 at which dissociation is to take place. The filament 244 may be fixedly connected to the inner sleeve 220a, in particular the top wall thereof, such that the electric terminals of the heating filament extend through the top wall to connect to two electrodes 240a,b that extend upwards, from within the outer reactor chamber 114, through the cover portion 112a of the wall of the outer reactor 112, to outside of the reactor 100, wherein the electrode terminals 242a,b may be connected to an electric power source (not shown).

The outer sleeve 220b may be generally tubular, and, measured along the central sleeve axis L, be longer, e.g. at least two or three times longer, than the inner sleeve 220a. An inner diameter of the outer sleeve 220b may preferably be larger than an outer diameter of the inner sleeve 220a, such that a circumferential, thermally insulating gap exists between the inner sleeve 220a and the outer sleeve 220b. Adjacent its lower end, the outer sleeve 220b may define an outlet opening 228 via which the reaction space is fluidly connected to the substrate processing chamber 158 of the inner reactor 150.

It will be clear that the position of the inner sleeve 220a, which is connected to the lower end of the inner tube 212a of the precursor gas supply tube 212, relative to the outer sleeve 220b may be varied by adjusting the position of the inner tube 212a relative to the outer tube 212b, as described above.

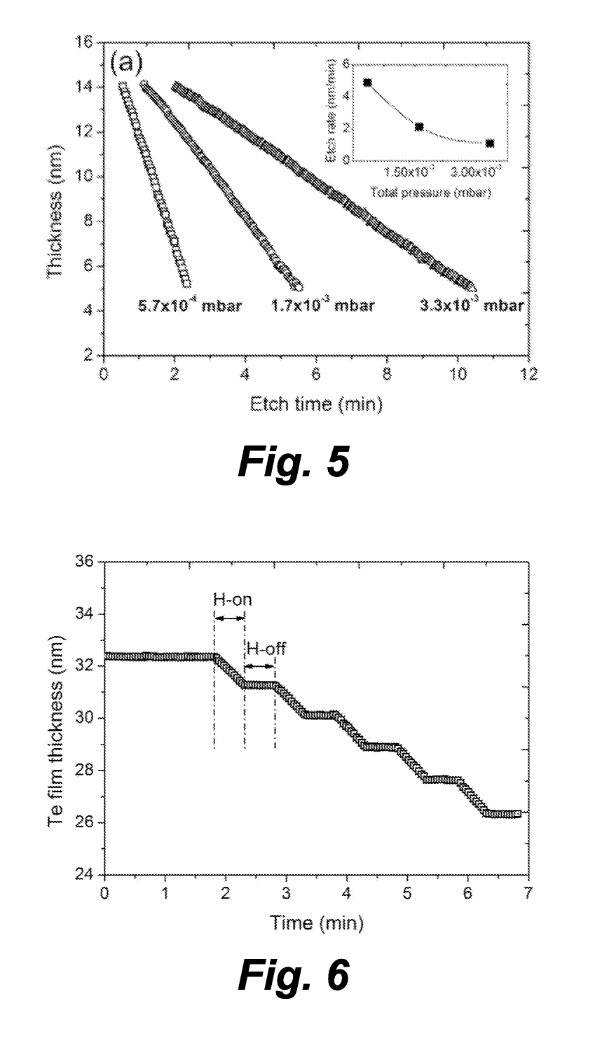

The configuration of the semiconductor processing apparatus 1 as a whole may preferably be such that there is substantially no line of sight between the heating filament 244 and the substrate support location 156, so as to ensure that a substrate 300, supported at said location 156, is not directly exposed to radiative heat from the heating filament 244 during operation. To this end, the sleeve 220 of the free radical source 200 may be disposed outside of the processing chamber 158, in such a way that the outlet opening 228 of the sleeve 200 is fluidly connected to the substrate processing chamber 158 via an opening in a bounding wall of the processing chamber 158, as in the depicted embodiment. Furthermore, the apparatus 1 may preferably be configured such that there is an unobstructed line of sight between the outlet opening 228 of the outer sleeve 220b and the substrate support location 156, such that, during operation, free radicals generated within the reaction space 222 of the sleeve 220 may flow substantially unobstructed, and in particular with a minimum of contacts with the relatively cold walls 152a,b bounding the process chamber 158 that may cause recombination and elimination of the free radicals, from the free radical source 200 prior to reaching the substrate 300. A distance between the outlet opening 228 and the substrate support location 156 may preferably be less than 50 cm, and more preferably less than 25 cm; for greater distances the recombination rate of the free radicals may become unfavorably high. FIG. 5 schematically shows results of an experiment carried out by means of the semiconductor processing apparatus shown in FIGS. 1-4, which demonstrate the effectivity of the presently disclosed free radical source 200. In the experiment, a tellurium (Te) film provided on a silicon substrate was etched with atomic hydrogen (H) generated by the source 200. The temperature of the heating filament 244 was about 1900° C., and the molecular hydrogen (H₂) feed to the source was 10 sccm. The rate at which the tellurium film was etched was measured as a function of time for three different processing chamber pressures: 5.7.10⁻⁴ mbar, 1.7.10⁻³ mbar and 3.3.10⁻³ mbar. The respective etch rates that were observed indicate the presence of significant amounts of atomic hydrogen. As is clear from FIG. 5, the etch rate decreased at higher pressures, presumably as a result of the decreasing life time of the atomic hydrogen due to recombination.

FIG. 6 schematically shows the results of another, related experiment in which the thickness of the tellurium film was measured as a function of time while the free radical source 200 was repetitively switched on and off in thirty second intervals. During the “on” periods, the film thickness decreased linearly with time; during the “off” periods, no decrease in film thickness was observed. The results lead to the expectation that pulse times in the order of one second, as used in Atomic Layer Deposition (ALD), may be realized with the presently disclosed free radical source.

Although illustrative embodiments of the present invention have been described above, in part with reference to the accompanying drawings, it is to be understood that the invention is not limited to these embodiments. Variations to the disclosed embodiments can be understood and effected by those skilled in the art in practicing the claimed invention, from a study of the drawings, the disclosure, and the appended claims. Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, it is noted that particular features, structures, or characteristics of one or more embodiments may be combined in any suitable manner to form new, not explicitly described embodiments.

### LIST OF ELEMENTS

1 semiconductor processing apparatus
100 reactor
110 outer reactor
112 wall of outer reactor
112a cover portion
114 outer reactor chamber
116 vacuum exhaust
118 substrate transport passage
150 inner reactor
152a,b bottom (a) and top (b) wall of inner reactor
154 wafer tray
156 substrate support location
158 inner reactor chamber/processing chamber
160 inlet opening
162 outlet opening
164 gas exhaust
200 free radical source
210 precursor gas supply tube assembly
212a,b first (a) and second (b) tube of precursor gas supply tube
213 clamp ring
214 support flange
216 sight-glass/inspection hole
218 precursor gas inlet
220a,b inner (a) and outer (b) sleeve
222 reaction space
224 inlet opening of inner sleeve
226 outlet opening of inner sleeve
228 outlet opening of outer sleeve
230 thermally insulating gap
240a,b electrode
242a,b terminal of electrode
244 heating filament
250 precursor gas source
300 substrate
L central sleeve axis

We claim:

1. A semiconductor processing apparatus, comprising:
a substrate processing chamber, defining a substrate support location at which a generally planar semiconductor substrate is supportable;
at least one free radical source, including:
a precursor gas source;
an electric resistance heating filament;
a sleeve with a central sleeve axis, wherein said sleeve defines a reaction space that accommodates the heating filament, and wherein said sleeve includes an inlet opening via which the reaction space is fluidly connected to the precursor gas source, and an outlet opening via which the reaction space is fluidly connected to the substrate processing chamber, said inlet and outlet openings being spaced apart along the central sleeve axis.

2. The semiconductor processing apparatus according to claim 1, wherein an external surface area of the heating filament is denoted A, wherein a volume of the reaction space is denoted V, and wherein a ratio A/V≧1.5/mm.

3. The semiconductor processing apparatus according to claim 1, wherein the precursor gas source is a molecular hydrogen (H₂) source.

4. The semiconductor processing apparatus according to claim 1, wherein the precursor gas source is an ammonia (NH₃) source.

5. The semiconductor processing apparatus according to claim 1, wherein the precursor gas source is a nitrous oxide (N₂O) source.

6. The semiconductor processing apparatus according to claim 1, wherein the heating filament includes a plurality of windings that extend helically around the central sleeve axis.

7. The semiconductor processing apparatus according to claim 1, wherein the heating filament is at least partially made of metal.

8. The semiconductor processing apparatus according to claim 7, wherein the heating filament is at least partially made of tungsten.

9. The semiconductor processing apparatus according to claim 1, wherein the sleeve is at least partially made of a ceramic material.

10. The semiconductor processing apparatus according to claim 9, wherein the sleeve is at least partially made of aluminum oxide (Al₂O₃).

11. The semiconductor processing apparatus according to claim 1, wherein the sleeve includes an outer sleeve and an inner sleeve that is movably received within the outer sleeve, and
wherein the inner sleeve defines the reaction space that accommodates the heating filament, and
wherein the outer sleeve defines the outlet opening via which the reaction space is fluidly connected to the substrate processing chamber.

12. The semiconductor processing apparatus according to claim 11, wherein an outer diameter of the inner sleeve is smaller than an inner diameter of the outer sleeve, such that a circumferential, thermally insulating gap exists between the inner sleeve and the outer sleeve.

13. The semiconductor processing apparatus according to claim 1, configured such that there is substantially no unobstructed line of sight between the heating filament and the substrate support location.

14. The semiconductor processing apparatus according to claim 1, configured such that there is a unobstructed line of sight between the outlet opening of the sleeve and the substrate support location.

15. The semiconductor processing apparatus according to claim 1, wherein a distance between the outlet opening of the sleeve and the substrate support location is less than 50 cm, and preferably less than 25 cm.

16. The semiconductor processing apparatus according to claim 1, wherein the sleeve of the free radical source is disposed outside of the processing chamber, such that the outlet opening of the sleeve is fluidly connected to the substrate processing chamber via an opening in a bounding wall of the processing chamber.

17. A method of exposing a semiconductor substrate to free radicals, comprising:
providing a semiconductor processing apparatus according to claim 1;
providing a substrate at the substrate support location in the processing chamber of the semiconductor processing apparatus;
heating the heating filament to a temperature of at least 1000° C., and preferably at least 1500° C.;
providing a flow of precursor gas from the precursor gas source into the reaction space of the sleeve, thereby causing dissociation of the precursor gas into at least one free radical species, and subsequently providing a flow of the free radical species from the reaction space to the substrate support location in the processing chamber, so as to expose the substrate to the free radical species.

18. The method according to claim 17, wherein the precursor gas includes molecular hydrogen (H₂), and
wherein the free radical species includes atomic hydrogen (H).

19. The method according to claim 17, wherein the precursor gas includes ammonia (NH₃), and
wherein the free radical species includes atomic hydrogen (H).

20. The method according to claim 17, wherein the precursor gas includes nitrous oxide (N₂O),
and wherein the free radical species includes atomic oxygen (O).

21. The method according to claim 17, wherein the heating filament is heated to a temperature of at least 1750° C.

22. The method according to claim 17, further comprising:
maintaining a pressure within the processing chamber below 1 Pa, and preferably below 0.1 Pa.
